(19) United States
(12) Patent Application Publication
(10) Pub. No.: US 2002/0094682 A1
(43) Pub. Date: Jul. 18, 2002

(54) Method for fabricating a III-V nitride film and an apparatus for fabricating the same

(75) Inventors: Tomohiko Shibata, Kasugai City (JP); Yukinori Nakamura, Nagoya City (JP); Mitsuhiro Tanaka, Handa City (JP); Keiichiro Asai, Nagoya City (JP)

Correspondence Address: BURR & BROWN, PO BOX 7068, SYRACUSE, NY, 13261-7068, US

(73) Assignee: NGK Insulators, Ltd., Nagoya City (JP)

(21) Appl. No.: 10/004,345

(22) Filed: Nov. 2, 2001

(30) Foreign Application Priority Data
Nov. 15, 2000 (JP) 2000-347,735

(51) Int. Cl. H01L 21/44

(52) U.S. Cl. 438/681; 438/661

(57) ABSTRACT

At least one of the interior wall of a reactor and a susceptor installed in the reactor is coated with an AlaGabIncN (a+b+c=1, a>0) film, which is heated to about 1000° C. or over when a substrate is heated to a predetermined temperature so as to generate the MOCVD reaction between a III raw material gas and a V raw material gas. Therefore, the AlpGaqInrN (p+q+r=1) compound generated from the raw material gases is deposited on the coated AlaGablncN (a+b+c=1, a>0) film, and thus, particles composed of the AlpGaqlnrN compound are not almost created. As a result, the resulting AlxGaylnzN (x+y+z=1) film is not affected by the particles, and can have its desirable quality.

### BACKGROUND OF THE INVENTION

(1) Field of the Invention

This invention relates to a method to epitaxially grow a III-V nitride film, particularly AlxGayInzN (x+y+z=1) film on a given substrate by a Metal Organic Chemical Vapor Deposition (MOCVD) method and an apparatus for the same method.

(2) Related Art Statement

In opto-electronic devices such as light-emitting diodes, laser diodes or photodiodes, it is proposed that Ill-V nitride films having their compositions of AlxGayInzN(X+Y+Z=1) is epitaxially grown on a given substrate made of sapphire single crystal, for example. Up to now, the epitaxial growth of the AlxGayInzN film has been performed by a MOCVD method or recently, a Hydride Vapor Phase Epitaxy (HVPE) method.

In the case of making a GaN film by a HVPE method, first of all, a substrate made of sapphire single crystal is set into a reactor in which a gallium metallic material is charged. Then, a hydrochloric acid gas is introduced into the reactor and reacted with the gallium metallic material, to generate a hydrochloric gallium gas. Then, an ammonia gas is introduced into the reactor and reacted with the hydrochloric gallium gas, to deposit and fabricate the GaN film on the substrate. The HVPE method has a higher film growth rate than a MOCVD method or a MOVPE method. For example, in the MOVPE method, a GaN film can be epitaxially grown typically at only several μm/hour, but in the HVPE method, the GaN film can be epitaxially grown typically at several hundreds μm/hour. Therefore, the HVPE method has its advantage in forming a thicker Ill-V nitride film.

However, a good quality AlxGayInzN film can not be provided by the HVPE method, and the fluctuation in thickness on the same substrate may be increased. On the other hand, it takes much time to form the AlxGaylnzN film by the MOVPE method, and thus, the fabrication cost of the AlxGaylnzN film rises.

In the case of making an AlxGayInzN (x+y+z=1) film by a MOCVD method, a given substrate is set and held on a susceptor installed in a reactor, and is heated to a predetermined temperature by a heater. Then, a trimethyl-aluminum gas, a trimethylgallium gas, a trimethylindium gas or the like as III raw material gases are introduced with a carrier gas composed of a hydrogen gas or a nitrogen gas into the reactor. On the other hand, an ammonia gas as a V raw material gas is introduced with a carrier gas composed of a hydrogen gas or a nitrogen gas into the reactor. Then, the III raw material gases and the V raw material gas are reacted, to deposit and form the AlxGayInzN film on the substrate. As the AlxGayInzN film, an aluminum nitride film, a gallium nitride film, an indium nitride film, an aluminum-gallium nitride film, an alumin-indium nitride film and a gallium-indium nitride film are exemplified.

In the above conventional method such as a MOCVD method, if the reaction between the III raw material gases and the V raw material gas is created on the wall surfaces of the reactor, the film-forming efficiency is degraded, and thus, the film growth rate is decreased. In the past, therefore, the raw material gases are cooled down at their introduction to the reactor, or the interior wall of the reactor are partially cooled down.

On the other hand, the ammonia gas as the V raw material gas exhibits its intensive corrosion property. Therefore, the heated parts of the interior wall of the reactor may be coated by a protective layer made of SiC, p-BN, TaCx, NbNx, etc., so as to prevent the corrosion of the interior wall. In this case, if the reaction between the III raw material gases and the V raw material gas is created on the wall surfaces of the reactor, the resulting AlpGaqInrN (p+q+r=1) compound is not deposited on the protective layer, but is drop off of the protective layer as particles.

Particularly, at the highly heated parts of the protective layer, more particles composed of the AlpGaqInrN compound are created through the gas phase reaction between the III raw material gases and the V raw material gas due to the catalytic effect of the interior wall of the reactor. In the case of using a trimethylaluminum gas as one of the III raw material gases for making an AlN film or an Al-rich AlxGayInzN (x+y+z=1, x>0.5) film, many particles are easily created due to the higher reactivity of the trimethylaluminum gas.

The resulting particles are drop off from on the protective layer, as mentioned above, and blown off by the raw material gases or the carrier gas and deposited onto a substrate. In this case, the quality of the resulting AlxGayInzN film, particularly an AIN film or an Al-rich AlxGayInzN film is deteriorated due to the deposited particles.

In addition, since the substrate on which the AlxGayInzN film is formed is heated through a susceptor which is initially heated with a heater, the surface temperature of the susceptor is raised to higher temperature of 1000° C. or over than the substrate temperature, so that more particles composed of the AlpGaqInrN compound are easily created on the surface of the susceptor. Then, the created particles are deposited on the substrate, and thus, the quality of the resulting AlxGayInzN film is deteriorated.

FIG. 1A is a conceptual view showing the film quality of an AlN film formed on a substrate made of a 3-inch wafer using a new susceptor. The quality deterioration of the AlN film is designated by the hatched region at the periphery of the substrate. As shown in FIG. 1A, the quality of the AlN film is remarkably deteriorated by using the new susceptor due to the particle deposition.

Moreover, when using such a large substrate as a 3-inch wafer so as to reduce the fabrication cost, the quality deterioration of the resulting AlxGayInzN film becomes remarkable due to more particles at the periphery of the substrate.

### SUMMARY OF THE INVENTION

It is an object of the present invention to work out the above conventional problems, and thus, to provide a method and an apparatus for epitaxially growing a good quality AlxGayInzN film (x+y+z=1) by a MOCVD method.

In order to achieve the above object, this invention relates to A method for fabricating a Ill-V nitride film, including the steps of preparing a substrate onto a susceptor in a reactor, heating the substrate to a predetermined temperature, coating an AlaGabIncN (a+b+c=1, a>0) film on an interior portion of a reactor which is heated to about 1000° C. or over through the heating for the substrate, and introducing a III raw material gas and a V raw material gas with a carrier gas onto the substrate prepared in the reactor, and thus, fabricating an AlxGayInzN (x+y+z=1) film by a MOCVD method.

The coated AlaGabIncN (a+b+c=1, a>0) film includes unavoidable elements such as oxygen element, silicon element, magnesium element and another element containing in the interior wall of the reactor by several %. Moreover, the AlaGabIncN film is not required to have a uniform composition over the total thickness, but may have a continuously or stepwisely inclined composition or an multi-layered structure composed of plural films having their respective different compositions.

In a preferred embodiment of the present invention, an AlaGabIncN (a+b+c=1, a>0) film is coated on the susceptor to hold the substrate. In the case of making a Ill-V nitride film by a MOCVD method, as mentioned above, the substrate is heated to around 1000° C., and thus, the surface of the susceptor is heated to 1000° C. or over. Therefore, more particles composed of the AlpGaqInrN (p+q+r=1) compound is likely to be created on the susceptor. However, if the susceptor is coated with the AlaGabIncN film, the AlpGaqInrN compound is deposited directly on the susceptor, and thus, the particles are not created and deposited on the substrate. As a result, the resulting AlxGayInzN film can have its desirable quality.

Herein, the particles means not only “particles having diameter of more than 0.1 μm”, but also “much smaller-scale intermediate products like polymers made from III raw materials, including especially aluminum and V raw materials.”

The fabricating method of the present invention may be preferably usable in forming an Al-rich AlxGayInzN (x+y+z=1, x>0.5) film or an AlN film by introducing into the reactor much amount of trimethylaluminum gas with an ammonia gas.

Particularly, in the case of making the Al-lich AlxGayInzN film or the AlN film, the AlaGabIncN film to be formed on the interior wall of the reactor and/or the susceptor includes relatively large amount of Al element, preferably 50 atomic percentages or over (a>0.5), more preferably 100 atomic percentages (a=1.0, that is, an AlN film). In this case, the Al-rich AlpGaqInrN compound is efficiently deposited on the Al-rich AlaGabIncN film coated on the susceptor and/or the interior wall of the reactor, and thus, the particles composed of the Al-rich AlpGaqInrN compound are not almost created.

This invention also relates to an apparatus for fabricating a III-V nitride film by a MOCVD method, including a reactor in which the MOCVD reaction between a III raw material gas and a V raw material gas is generated, a susceptor to hold a substrate thereon installed in the reactor, a heater to heat the substrate to a predetermined temperature via the susceptor, at least one of the interior wall of the reactor and the susceptor is coated with an AlaGabIncN (a+b+c=1, a>0) film, which is heated to 1000° C. or over.

In the fabricating apparatus of the present invention, too, the interior wall of the reactor and/or the susceptor is preferably coated with an Al-rich AlaGabIncN film or an AlN film when an Al-rich AlxCaylnzN film or an AlN film is made by a MOCVD method using a III raw material gas such as a trimethylaluminum gas and a V raw material gas such as an ammonia gas, as mentioned above. Therefore, the fabricating method of the present invention may be preferably usable in forming an Al-rich AlxGayInzN (x+y+z=1, x>0.5) film or an AlN film by introducing into the reactor much amount of trimethylaluminum gas with an ammonia gas.

### BRIEF DESCRIPTION OF THE DRAWINGS

For better understanding of the present invention, reference is made to the attached drawings, wherein

FIG. 1A is a conceptual view showing the film quality of an AlN film formed on a substrate made of a 3-inch wafer, according to the present invention,

FIG. 1B is a conceptual view showing the film quality of an AlN film, according to the present invention,

FIG. 2 is a cross sectional view diagrammatically showing the structure of a fabricating apparatus for a Ill-V nitride film according to the present invention,

FIG. 3 is a cross sectional view showing the susceptor of the fabricating apparatus, and

FIG. 4 is a cross sectional view showing the susceptor of another fabricating apparatus according to the present invention.

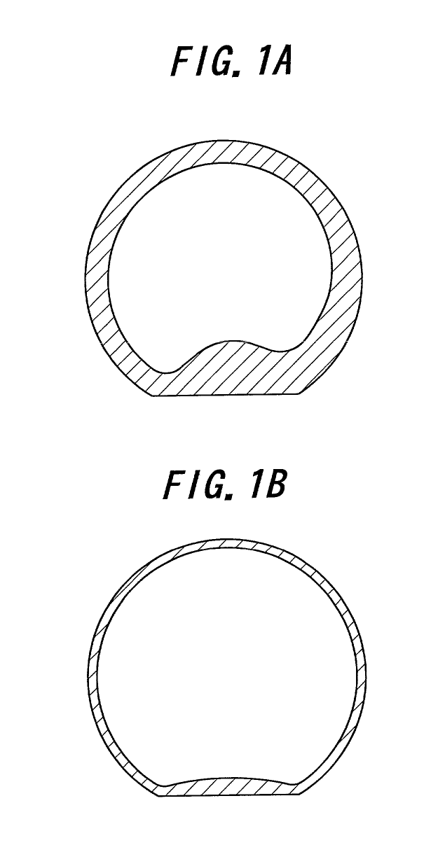

### DESCRIPTION OF THE PREFERRED EMBODIMENTS

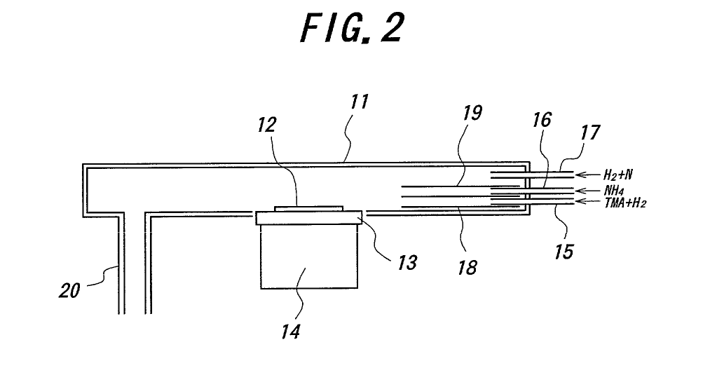

FIG. 2 is a cross sectional view diagrammatically showing the structure of a fabricating apparatus for a Ill-V nitride film according to the present invention. In FIG. 2, the fabricating apparatus includes a reactor 11 made of quartz or stainless, a susceptor 13 at the center in the lower side of the reactor and a heater 14 under the susceptor 13. A substrate 12 made of, e.g., sapphire single crystal is set horizontally on the susceptor and heated to a predetermined temperature with the heater. Although, in FIG. 2, the substrate is held on the upper surface of the susceptor, it may be held on the lower surface.

At the right side of the reactor 11 are provided gas inlets 15-17 to introduce raw material gases with a carrier gas. In the case of making an AlN film, for example, a trimethylaluminum gas is introduced with a hydrogen carrier gas from the first gas inlet 15, and an ammonia gas is introduced from the second gas inlet 16. Then, a carrier gas composed of a hydrogen gas or a nitrogen gas is introduced from the third gas inlet 17. The introduced trimethylaluminum gas and the introduced ammonia gas are also introduced into the center region of the reactor through separated guiding tubes 18 and 19, respectively. In this case, the raw material gases are effectively supplied onto the substrate 12, and not supplied in the remote region from the substrate 12. The introduced raw material gases are consumed by a MOCVD reaction on the substrate, and the remaining raw material gases are discharged from gas outlet 20 provided at the left side of the reactor 11.

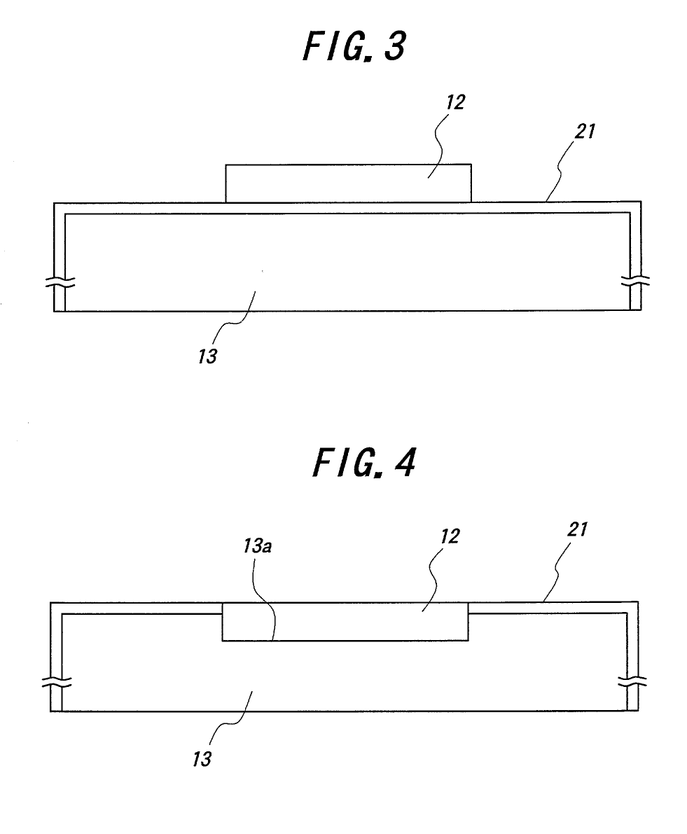

In the case of making an AlN film, the substrate 12 is heated to around 1000° C., for example by the heater 14. In this case, the surface temperature of the susceptor 13 is raised to 1000° C. or over. Therefore, the raw material gases are likely to be chemically reacted on the susceptor, to create particles composed of the AlNx compound. The particles are blown off by the raw material gases and the carrier gases and deposited on the substrate 12, to deteriorate the quality of the AlxGayInzN film, for example, an AlN film. Therefore, as shown in FIG. 3, for example, an AlN film 21 is coated in a thickness of 1 μm on the top surface and the side surfaces of the susceptor 13. In this case, the AlNx compound is deposited on the coated AlN film 21, and thus, particles composed of the AlNx compound are not almost created. As a result, the resulting AlN film is not affected by the particles, and can have its desirable quality over the almost entire main surface of the substrate including the periphery thereof. Accordingly, the fabricating total cost of the AIN film can be reduced.

Although the present invention was described in detail with reference to the above example, this invention is not limited to the above disclosure and every kind of variation and modification may be made without departing from the scope of the present invention.

For example, the AIN film 21 may be coated on the interior walls of the reactor and/or another instrument installed in the reactor which are heated to higher temperature of 1000° C. or over, instead of coating over the susceptor 13. Then, besides the AlN film, another AlaGablncN (a+b+c=1, a>0) film or AlaGablncN (a+b+c=1, a>0.5) film may be coated.

The substrate 12 may be made of, instead of the sapphire single crystal, oxide single crystal such as ZnO single crystal, LiAlO₂ single crystal, LiGaO₂ single crystal, MgAl₂O₄ single crystal, or MgO single crystal, IV single crystal or IV-IV single crystal such as Si single crystal or SiC single crystal, III-V single crystal such as GaAs single crystal, AIN single crystal, GaN single crystal or AlGaN single crystal, and boride single crystal such as ZrB₂. Moreover, the substrate 12 may be composed of an epitaxial substrate having such a single crystal as mentioned above as a base material and a given epitaxial film formed on the base material.

The substrate 12 may be set in a grooved portion 13a formed at the plane main surface of the susceptor 13 as shown in FIG. 4, instead of being set directly on the plane main surface of the susceptor 13. In this case, for not disturbing the raw material gas flow on the substrate 12, it is desired that the grooved portion is formed so that the surface level of the substrate 12 set into the grooved portion can be the same as the surface level of the coated AIN film 21. Moreover, the AlN film 21 may not be coated at the connection between the substrate 12 and the susceptor 13 and/or the side surfaces of the susceptor 13 to which the raw material gases are not directly contacted.

As mentioned above, according to the fabricating method and the fabricating apparatus for a Ill-V nitride film of the present invention, an AlaGabIncN (a+b+c=1, a>0) film, particularly an Al-rich AlaGabIncN (a+b+c=1, a>0.5) film, more particularly an Al film is coated on an interior portion of the reactor which is heated to 1000° C. or over. Therefore, the AlpGaqInrN (p+q+r=1) compound generated through the reaction of the raw material gases is deposited on the coated film, and thus, particles made of the AlpGaqInrN compound are not almost created. As a result, the resulting AlxGayInzN film is not affected by the particles, and can have its desirable quality. In addition, the interior portion including the interior wall of the reactor is not almost corroded by an ammonia gas as a V raw material gas because the coated film functions as an anti-corrosive film, so that the durability of the whole fabricating apparatus can be developed.

What is claimed is:

1. A method for fabricating a III-V nitride film, comprising the steps of:
preparing a substrate onto a susceptor in a reactor,
heating the substrate to a predetermined temperature,
coating an AlaGablncN (a+b+c=1, a>0) film on an interior portion of a reactor which is heated to about 1000° C. or over through the heating for the substrate, and
introducing a III raw material gas and a V raw material gas with a carrier gas onto the substrate prepared in the reactor, and thus, fabricating an AlxGayInzN (x+y+z=1) film by a MOCVD method.

2. A fabricating method as defined in claim 1, wherein the AlaGabIncN film is coated on the susceptor which is heated to about 1000° C. or over.

3. A fabricating method as defined in claim 1, wherein the AlaGabIncN (a+b+c=1, a>0) film includes 50 atomic percentages or over of Al element (a>0.5) for all of the III elements.

4. A fabricating method as defined in claim 3, wherein the AlaGablncN (a+b+c=1, a>0) film is composed of an AlN film.

5. A fabricating method as defined in claim 3, wherein the AlxGayInzN (x+y+z=1) film includes 50 atomic percentages or over of Al element (a>0.5) for all of the III elements.

6. A fabricating method as defined in claim 3, wherein the AlxGaylnzN (x+y+z=1) film is composed of an AlN film.

7. An apparatus for fabricating a Ill-V nitride film by a MOCVD method, comprising:
a reactor in which the MOCVD reaction between a III raw material gas and a V material gas is generated,
a susceptor to hold a substrate thereon installed in the reactor,
a heater to heat the substrate to a predetermined temperature via the susceptor,
at least one of the interior wall of the reactor and the susceptor is coated with an AlaGablncN (a+b+c=1, a>0) film, which is heated to 1000° C. or over.

8. A fabricating apparatus as defined in claim 7, wherein the AlaGablncN (a+b+c=1, a>0) film includes 50 atomic percentages or over of Al element (a>0.5) for all of the III elements.

9. A fabricating apparatus as defined in claim 8, wherein the AlaGablncN (a+b+c=1, a>0) film is composed of an AlN film.
